(19) United States
(12) Patent Application Publication
(10) Pub. No.: US 2006/0014389 A1
(43) Pub. Date: Jan. 19, 2006

(54) Method of manufacturing semiconductor device

(76) Inventor: Jun Osanai, Chiba-shi (JP)

Correspondence Address: BRUCE L. ADAMS, ESQ., SUITE 1231, 17 BATTERY PLACE, NEW YORK, NY, 10004, US

(21) Appl. No.: 11/178,745

(22) Filed: Jul. 11, 2005

(30) Foreign Application Priority Data
Jul. 14, 2004 (JP) 2004-207222

(51) Int. Cl. H01L 21/44

(52) U.S. Cl. 438/684; 438/233

(57) ABSTRACT

In a MOS semiconductor device in which a SOI substrate made of an extremely thin film is used, a polycrystalline silicon film is formed through contact holes provided in a thin insulating film on a source and a drain. Then, a relatively thick insulating film is provided thereon and formed with contact holes. An electrical junction between a metal wiring and the source and drain is established through the polycrystalline silicon film.

### BACKGROUND OF THE INVENTION

1. Field of the Invention

The present invention relates to a method of manufacturing a semiconductor device for low voltage operation, low power consumption, and high-speed operation, formed on an SOI substrate using an extremely thin film.

2. Description of the Related Art

A MOS semiconductor device formed on an SOI (Silicon On Insulator) substrate whose active layer has a thickness of 100 nm or less, can operate in a complete depletion mode, and can also operate at lower voltage compared to a conventional semiconductor device in which a bulk semiconductor substrate is used. Accordingly low power consumption and higher speed operation due to its small parasitic capacitance are attained.

When the thickness of the active layer is further reduced in order to improve performance of the semiconductor devices formed on an SOI substrate, a problem occurs in which the bottom of contact holes, which electrically connect a source and a drain of a MOS transistor with metal wirings, reaches an insulating film under the active layer at the time of the contact hole formation because the active layer is thin, resulting in insufficient contacts.

In order to solve the problem, for example, JP 05-326556 A discloses a method in which single crystal is grown on a source and a drain. FIG. 4 shows a MOS transistor having single crystal silicon 215 grown on the source and drain regions 204.

The structure shown in the prior art has a problem that a crystal defect may be generated in single crystal growth by variation in apparatus setting, and the crystal growth cannot be made stably. Further, it is also disadvantageous that an apparatus for single-crystal growth is expensive and therefore the cost of the semiconductor device manufactured by this apparatus is also high.

### SUMMARY OF THE INVENTION

The present invention has been made in view of the above, and an object of the present invention is to provide a method of manufacturing a MOS semiconductor device which can be manufactured stably for low voltage operation, low power consumption, and high-speed operation, formed on an SOI substrate using an extremely thin film.

In order to achieve the object, the following means are adopted in the present invention. The present invention provides:

(1) A method of manufacturing a semiconductor device comprising the steps of: forming a first insulating film on a source and a drain of a MOS transistor formed in a single crystalline semiconductor on an insulating film; forming first contact holes selectively in the first insulating film on the source and the drain, respectively; depositing a polycrystalline silicon film; selectively ion implanting impurities by setting a peak of an impurity profile at an interface between the polycrystalline silicon film and the source and the drain; forming a second insulating film thereon; forming second contact holes selectively in the second insulating film; and forming a metal wiring thereon.

(2) A method of manufacturing a semiconductor device in which the polycrystalline silicon film has a thickness of from 50 nm to 200 nm.

(3) A method of manufacturing a semiconductor device in which the first insulating film has a thickness of from 50 nm to 200 nm.

(4) A method of manufacturing a semiconductor device in which, as the impurities, phosphorous is introduced into an NMOS region with a dosage of from 1×10¹⁵/cm² to 5×10¹⁵/cm², and boron or BF₂ is introduced into a PMOS region with a dosage of from 1×10¹⁵/cm² to 5×10¹⁵/cm².

As described above, according to the manufacturing method disclosed in the present invention, a MOS semiconductor device which can be manufactured stably for low voltage operation, low power consumption, and high-speed operation, formed on an SOI substrate using an extremely thin film, is provided.

### BRIEF DESCRIPTION OF THE DRAWINGS

In the accompanying drawings:

FIG. 1 is a schematic sectional view showing a method of manufacturing a semiconductor device in accordance with an embodiment of the present invention;

FIG. 2 is a schematic sectional view showing the method of manufacturing a semiconductor device in accordance with the embodiment of the present invention;

FIG. 3 is a schematic sectional view showing the method of manufacturing a semiconductor device in accordance with the embodiment of the present invention; and

FIG. 4 is a schematic sectional view showing a conventional semiconductor device.

### DETAILED DESCRIPTION OF THE PREFERRED EMBODIMENTS

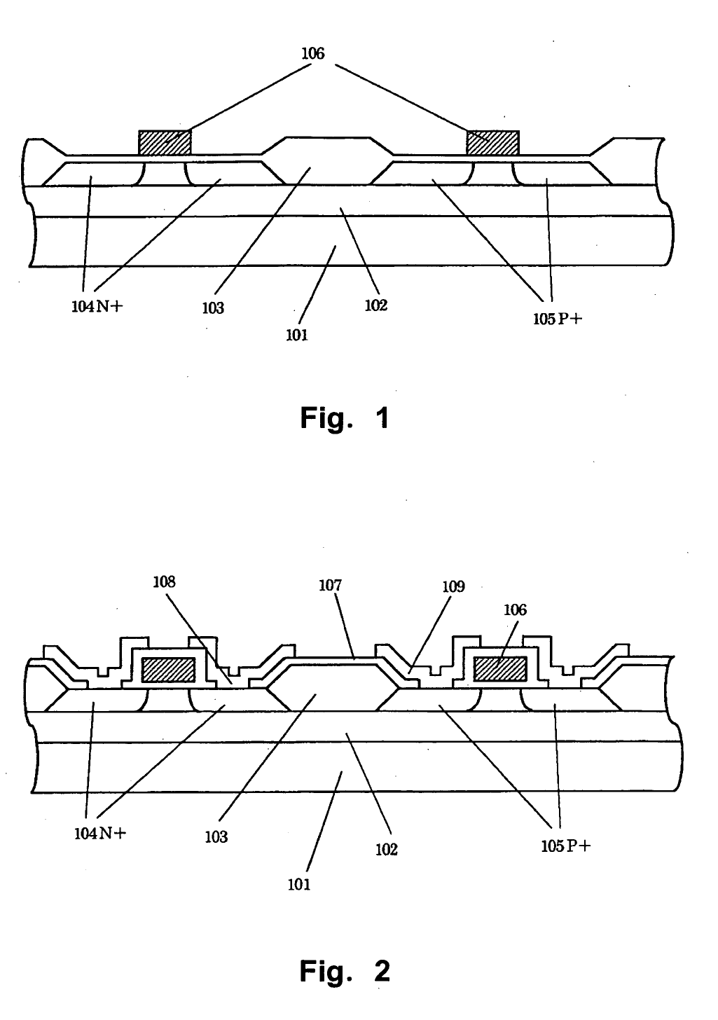

Hereinafter, description will be made to an embodiment of a method of manufacturing a semiconductor device according to the present invention with reference to the drawings. FIGS. 1 to 3 show the method of manufacturing a semiconductor device in accordance with the embodiment of the present invention.

FIG. 1 shows an NMOS and a PMOS which are formed in a semiconductor active layer on a buried insulating film 102 formed on a supporting substrate 101 through general steps of forming a standard MOS transistor. The NMOS and the PMOS are completely insulated and separated from each other by a field insulating film 103 and the buried insulating film 102. In order to operate in a complete depletion mode, the thickness of the active layer is set to 100 nm or less. The NMOS transistor has N+ source and drain regions 104 and the PMOS has P+ source and drain regions 105. Each of the transistors has a gate electrode 106.

FIG. 2 shows the selectively patterned polycrystalline silicon film on the source and the drain regions formed by the following steps. A first insulating film 107 is deposited to have a thickness of 50 nm to 200 nm by CVD (chemical vapor deposition). Then, first contact holes 108 are formed in the first insulating film on a source and a drain by photolithography and wet etching. Next, a polycrystalline silicon film 109 is deposited to have a thickness of 50 nm to 200 nm by LPCVD (low pressure CVD). Subsequently, a photoresist is patterned by photolithography to selectively form openings in the NMOS region, and phosphorous as an N-type impurity is introduced into the polycrystalline silicon film on the NMOS by ion implantation. Thereafter, the photoresist is removed. Next, a photoresist is patterned by photolithography such that the PMOS region is opened selectively, and boron or BF₂ as a P-type impurity is introduced into the polycrystalline silicon film on the PMOS by ion implantation. Thereafter, the, photoresist is removed. Subsequently, the polycrystalline silicon film is selectively patterned on the source and the drain by photolithography and dry etching. The first insulating film is, for example, a silicon oxide film. After the film formation, the film may be subjected to heat treatment for the improvement of the film quality.

Wet etching is used to form the contact holes in the first insulating film. Since selective ratio of the oxide film to silicon in wet etching is extremely large, the contact holes do not reach the buried insulating film even if the active layer of the SOI is extremely thin. For this reason, wet etching is adopted. However, when the first insulating film 107 is thick, undesirable side etch in wet etching is large, which is not suited for the formation of fine patterns. The thickness of the first insulating film 107 should thus be reduced to 200 nm or less within such a range that retains insulation. If the first insulating film is excessively thin (50 nm or less), the thickness of the film is hardly controlled, and there arises a difficulty in insulation.

It is sufficient when the thickness of the polycrystalline silicon film 109 falls within a range in which the film does not disappear at the formation of second contact holes described later. When the polycrystalline silicon film 109 has a thickness of 50 nm or less, the film may disappear in the second contact hole formation; on the contrary, when the polycrystalline silicon film 109 has a thickness of 200 nm or more, there arises a difficulty in miniaturization.

Since the polycrystalline silicon film is deposited without doping, contact resistance between the non-doped polycrystalline silicon film and the source or drain is not low. Thus, the impurities are introduced into the polycrystalline silicon film, thereby lowering the contact resistance. In the NMOS region phosphorous ion as a dopant is implanted with a dosage of from 1×10¹⁵/cm² to 5×10¹⁵/cm². And in the PMOS region boron or BF₂ ion as a dopant is implanted with a dosage of from 1×10¹⁵/cm² to 5×10¹⁵/cm². Acceleration energy in ion implantation is set such that a peak of a projection range is located at the interface between the source/drain and the polycrystalline silicon film to effectively lower the contact resistance.

It has been described that patterning of the polycrystalline silicon film is performed after ion implantation. However, patterning of the polycrystalline silicon film can be performed before ion implantation. Further, there may be a case where heat treatment is needed to activate the impurities at temperature of, for example, 800° C. to 900° C.

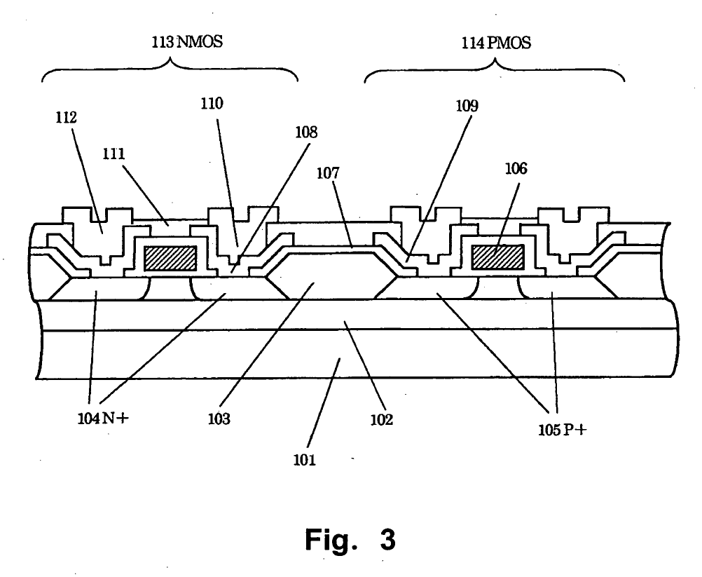

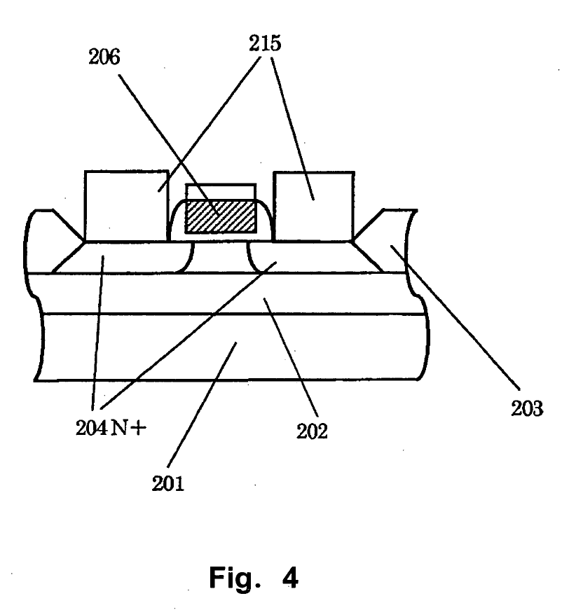

FIG. 3 shows a semiconductor device after metal patterning due to the following process steps. A second insulating film 111 is deposited by CVD, and then, a necessary leveling process is performed thereon. Second contact holes 110 are formed on the second insulating film 111 on the source and the drain by photolithography and dry etching. Subsequently, a metal 112 is deposited by sputtering, and the metal is then subjected to patterning by photolithography and dry etching.

Dry etching is used to form the second contact holes. Since the polycrystalline silicon film with a sufficient thickness is provided on the source and the drain, there does not arise a problem in which the contact holes reach the buried insulating film, which has occurred in the prior art.

Using the above-described manufacturing method in the contact-hole formation for obtaining the electrical junction between the metal wiring and the source and drain, the contact holes do not reach the buried insulating film even if the active layer of the SOI becomes thin, since the polycrystalline silicon film is provided on the source and the drain surface. Stable manufacturing can therefore be attained.

The embodiment shows the so-called single drain structure for the MOS structure. However, the same manufacturing method can also be applied to an LDD (lightly doped drain) structure or a drain extension structure, and the same effects as those in the embodiment can also be obtained in each structure.

Further, the embodiment can be implemented by using the apparatus widely spread in manufacturing of semiconductors. There is no need to use an expensive apparatus.

What is claimed is:

1. A method of manufacturing a semiconductor device, comprising the steps of:
forming a first insulating film on a source and a drain of a MOS transistor formed in a single crystalline semiconductor film on an insulating film;
forming first contact holes selectively in the first insulating film on the source and the drain, respectively;
depositing a polycrystalline silicon film thereon;
selectively ion-implanting impurities by setting a peak of an impurity profile at an interface between the polycrystalline silicon film and the source and the drain;
forming a second insulating film thereon;
forming second contact holes selectively in the second insulating film; and
forming a metal wiring thereon.

2. A method of manufacturing a semiconductor device according to claim 1, wherein the polycrystalline silicon film has a thickness of from 50 nm to 200 nm.

3. A method of manufacturing a semiconductor device according to claim 1, wherein the first insulating film has a thickness of from 50 nm to 200 nm.

4. A method of manufacturing a semiconductor device according to claim 1, wherein phosphorous is introduced into an NMOS region with a dosage of from 1×10¹⁵/cm² to 5×10¹⁵/cm², and boron or BF₂ is introduced into a PMOS region with a dosage of from 1×10¹⁵/cm² to 5×10¹⁵/cm², as the impurities.
